(19) United States
(12) Patent Application Publication
(10) Pub. No.: US 2025/0093396 A1
(43) Pub. Date: Mar. 20, 2025

(54) DEVICES AND METHODS FOR MEASURING HIGH-TEMPERATURE RESISTIVITY OF TIN OXIDE ELECTRODES IN SUBSTRATE GLASS FURNACES

(71) Applicant: CAIHONG DISPLAY DEVICES CO., LTD., Xianyang (CN)

(72) Inventors: Longjiang ZHAO, Xianyang (CN); Wei YANG, Xianyang (CN); Jian XU, Xianyang (CN); Dacheng WANG, Xianyang (CN); Weidong HU, Xianyang (CN)

(73) Assignee: CAIHONG DISPLAY DEVICES CO., LTD., Xianyang (CN)

(21) Appl. No.: 18/970,780

(22) Filed: Dec. 5, 2024

Related U.S. Application Data
(63) Continuation-in-part of application No. PCT/CN2024/092922, filed on May 13, 2024.

(30) Foreign Application Priority Data
Sep. 4, 2023 (CN) 202311132410.7

(51) Int. Cl. G01R 27/02

(52) U.S. Cl. CPC G01R 27/02

(57) ABSTRACT

The present disclosure provides a device and method for measuring a high-temperature resistivity of a tin oxide electrode in a substrate glass furnace, which relates to the field of high-temperature resistivity measurement of tin oxide electrodes. The two ends of a columnar tin oxide electrode are provided with platinum terminals, which are connected to a direct-current dual-arm bridge using platinum wires. The upper and lower side of the columnar tin oxide electrode are provided with fixed insulating spacers that are made of an aluminum oxide material. The device is placed in a high-temperature pit furnace. A heating program is set up to measure the corresponding values of the direct-current dual-arm bridge at different temperatures. Based on the resistivity calculating principle, the volume resistivities of the tin oxide electrode corresponding to different temperatures are calculated, which provide an electrical parameter reference for electrode melting of high-generation substrate glass when applying electricity.

### CROSS-REFERENCE TO RELATED APPLICATIONS

This application is a Continuation-in-part of International Application No. PCT/CN2024/092922, filed on May 13, 2024, which claims priority to Chinese Patent Application No. 202311132410.7, filed on Sep. 4, 2023, the entire contents of each of which are hereby incorporated by reference.

### TECHNICAL FIELD

The present disclosure relates to the field of high-temperature resistivity measurement of tin oxide electrodes, and in particular, to devices and methods for measuring the high-temperature resistivity of tin oxide electrodes in substrate glass furnaces.

### BACKGROUND

Glass products have a wide application range in the display field. Without the support of the glass industry, the development of the display industry would be unimaginable. Although other materials can partially replace glass in specific applications, they still cannot match the excellent performance of glass. From the traditional color cathode ray tube industry to the current flat panel display industry, glass has always played a crucial role as a key component in display devices. Glass essentially forms the framework and carrier of the entire device and acts as an optical element. When glass is used as the upper and lower substrates of a flat panel display device, it requires precise micro-semiconductor processing techniques.

In the manufacturing process of substrate glass, the raw glass liquid is first input into the feeding port of the furnace stably and smoothly and then melted, clarified, and homogenized in the furnace, so as to provide qualified and homogeneous glass liquid for the next process. The glass liquid after melting in the furnace is alkali-free high-alumina borosilicate glass, which is mainly used as substrate glass for flat panel displays. With the increase in the extraction volume of substrate glass with high generation, large feeding capacity, and ultra-precision, higher requirements are inevitably put forward for the melting capacity of the furnace and the setup of the electric heating parameters of the tin oxide electrodes.

Therefore, it is desired to provide a device and a method for measuring a high-temperature resistivity of a tin oxide electrode in a substrate glass furnace. By accurately measuring the high-temperature volume resistivity of a tin oxide electrode of a heating element of the furnace at different temperatures, strong theoretical support and basis are provided for the current and power settings when the electrode is powered, so as to solve the problem that it is difficult to precise control of electrical parameters of the tin oxide electrode in the melting process of glass melt in the furnace.

### SUMMARY

One or more embodiments of the present disclosure provide a device for measuring a high-temperature resistivity of a tin oxide electrode in a substrate glass furnace. The device may include a direct-current dual-arm bridge. One end of the direct-current dual-arm bridge may be connected to one end of a first platinum wire, and the other end of the direct-current dual-arm bridge may be connected to one end of a second platinum wire. The other end of the first platinum wire may be connected to a first platinum terminal, and a first insulating spacer is provided on an upper side of the first platinum terminal. The other end of the second platinum wire may be connected to a second platinum terminal, and a second insulating spacer is provided on a lower side of the second platinum terminal.

In some embodiments, the first insulating spacer and the second insulating spacer may be made of an aluminum oxide material.

In some embodiments, the alumina oxide material may have a resistivity of greater than 1×10³ Ω·cm above 1200° C., and an alumina oxide purity of the alumina oxide material may be no less than 99.99%.

In some embodiments, the first platinum terminal and the second platinum terminal may be symmetrically provided.

In some embodiments, a predetermined distance may be maintained between the first platinum terminal and the second platinum terminal, the predetermined distance being greater than a height of a columnar tin oxide electrode to be measured.

One or more embodiments of the present disclosure provide a method for measuring a high-temperature resistivity of a tin oxide electrode in a substrate glass furnace. The method may include after measuring a height and a cross-sectional diameter of a columnar tin oxide electrode to be measured, connecting two ends of the columnar tin oxide electrode to be measured to the first platinum terminal and the second platinum terminal, respectively, and connecting the two ends of the columnar tin oxide electrode to be measured to the direct-current dual-arm bridge through the first platinum wire and the second platinum wire. The method may also include after fixing the two ends of the columnar tin oxide electrode to be measured by employing a first insulating spacer and a second insulating spacer, placing the device in a high-temperature pit furnace. The method may also include obtaining a resistance value of the columnar tin oxide electrode to be measured using the direct-current dual-arm bridge at a predetermined temperature. The method may further include obtaining a resistivity of the columnar tin oxide electrode to be measured by a resistivity calculating principle based on the height, the cross-sectional diameter, and the resistance value of the columnar tin oxide electrode to be measured.

In some embodiments, the predetermined temperature may be within a range of 400° C.-1600° C.

In some embodiments, a heating rate of the predetermined temperature may be within a range of 4° C./min-6° C./min.

In some embodiments, the process of obtaining a resistance value of the columnar tin oxide electrode to be measured using the direct-current dual-arm bridge at a predetermined temperature may include measuring and recording, at intervals of 100° C., the resistance value of the columnar tin oxide electrode to be measured using the direct-current dual-arm bridge at the predetermined temperature.

In some embodiments, the resistivity calculating principle may include:

$${ρ}_{T} = \frac{R S}{L}$$

$$S = π \times \frac{{D}^{2}}{4}$$

where ρ_{T} may denote the resistivity of the columnar tin oxide electrode to be measured, R may denote the resistance value of the columnar tin oxide electrode to be measured, S may denote a cross-sectional area of the columnar tin oxide electrode to be measured, D may denote the cross-sectional diameter of the columnar tin oxide electrode to be measured, and L denotes the height of the columnar tin oxide electrode to be measured.

The present disclosure may include may not be limited to the following beneficial effects.

The embodiments of the present disclosure provide a device for measuring a high-temperature resistivity of a tin oxide electrode in a substrate glass furnace, which adopts a direct-current dual-arm bridge to measure the resistance value of the tin oxide electrode, connects platinum terminals at both ends of the tin oxide electrode through platinum wires, and provides the insulating spacers on sides of the platinum terminals. The measurement principle of this device is simple and the structural cost of the device is very low, which realizes the use of the production line process data for repeated comparison verification and repeated reproduction testing, saving expensive equipment costs and outsourcing test costs, thereby reducing production costs. The first insulating spacer and the second insulating spacer are both made of the aluminum oxide material with a purity of not less than 99.99%, which ensures stability during the measurement process. The embodiment of the present disclosure provides a method for measuring a high-temperature resistivity of a tin oxide electrode in a substrate glass furnace. The height and the diameter of the columnar tin oxide electrode to be measured are first measured. The resistance values of the columnar tin oxide electrode at different temperatures are then measured using the measuring device described above. Finally, the resistivities of the columnar tin oxide electrode to be measured at different temperatures are obtained according to the resistivity calculating principle. The method can provide strong theoretical support for the setting/application and accurate calculation of the electrical parameters of the tin oxide electrode within the process temperature interval of the production line process.

### BRIEF DESCRIPTION OF THE DRAWINGS

The present disclosure is further illustrated in terms of exemplary embodiments. These exemplary embodiments are described in detail with reference to the drawings. These embodiments are non-limiting exemplary embodiments, in which like reference numerals represent similar structures, and wherein:

FIG. 1 is a schematic diagram illustrating an exemplary device for measuring a high-temperature resistivity of a tin oxide electrode in a substrate glass furnace according to some embodiments of the present disclosure; and

FIG. 2 is a flowchart illustrating an exemplary method for measuring a high-temperature resistivity of a tin oxide electrode in a substrate glass furnace according to some embodiments of the present disclosure.

The following are descriptions of marks of accompanying drawings.
100: device for measuring a high-temperature resistivity of a tin oxide electrode in a substrate glass furnace; 110: direct-current dual-arm bridge; 120: first platinum wire; 130: second platinum wire; 140: first platinum terminal; 150: second platinum terminal; 160: first insulating spacer; 170: second insulating spacer; and 180: columnar tin oxide electrode to be measured.

### DETAILED DESCRIPTION

To more clearly illustrate the technical solutions related to the embodiments of the present disclosure, a brief introduction of the drawings referred to the description of the embodiments is provided below. Obviously, the drawings described below are only some examples or embodiments of the present disclosure. Those having ordinary skills in the art, without further creative efforts, may apply the present disclosure to other similar scenarios according to these drawings. Unless obviously obtained from the context or the context illustrates otherwise, the same numeral in the drawings refers to the same structure or operation.

It should be understood that “system,” “device,” “unit” and/or “module” as used herein is a manner used to distinguish different components, elements, parts, sections, or assemblies at different levels. However, if other words serve the same purpose, the words may be replaced by other expressions.

As shown in the present disclosure and claims, the words “one,” “a,” “a kind” and/or “the” are not especially singular but may include the plural unless the context expressly suggests otherwise. In general, the terms “comprise,” “comprises,” “comprising,” “include,” “includes,” and/or “including,” merely prompt to include operations and elements that have been clearly identified, and these operations and elements do not constitute an exclusive listing. The methods or devices may also include other operations or elements.

The flowcharts used in the present disclosure illustrate operations that systems implement according to some embodiments of the present disclosure. It should be understood that the previous or subsequent operations may not be accurately implemented in order. Instead, each step may be processed in reverse order or simultaneously. Meanwhile, other operations may also be added to these processes, or a certain step or several steps may be removed from these processes.

In the description of the present disclosure, it is to be understood that the terms “center,” “longitudinal,” “transverse,” “length,” “width,” “thickness,” “upper,” “lower,” “front,” “back,” “left,” “right,” “vertical,” “horizontal,” “top,” “bottom,” “inside,” “outside,” “clockwise,” “counterclockwise,” “axial,” “radial,” “circumferential,” or the like indicate orientation or positional relationships based on those shown in the accompanying drawings only to facilitate the description of the present disclosure and simplify the description, and are not intended to indicate or imply that the device or element referred to must be constructed or operated in a particular orientation, thus are not to be construed as a limitation of the present disclosure.

Additionally, the terms “first” and “second” are used only for descriptive purposes and are not to be construed as indicating or implying relative importance or implicitly specifying the number of technical features indicated. Thus, the features defined as “first” and “second” may expressly or impliedly include one or more of the technical features. In the description of the present disclosure, “more than one” means two or more, unless expressly and specifically limited otherwise.

In the present disclosure, unless otherwise expressly specified or limited, the terms “mounting,” “connecting,” “bonding,” “fixing,” etc., are to be understood in a broad sense, e.g., as a fixed connection, a removable connection, or a one-piece connection; a mechanical connection, an electrical connection, or a communication connection; a direct connection, or an indirect connection through an intermediary medium; or a connection within two elements or an interactive relationship between the two elements. To one of ordinary skills in the art, the specific meanings of the foregoing terms in the present disclosure may be understood on a case-by-case basis.

Embodiments of the present disclosure are described in detail as below in connection with the accompanying drawings.

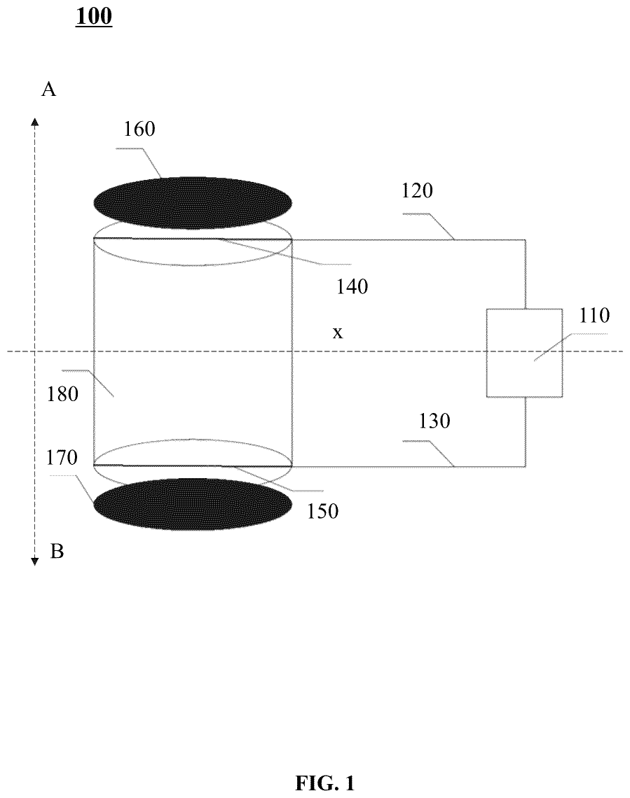

FIG. 1 is a schematic diagram illustrating an exemplary device for measuring a high-temperature resistivity of a tin oxide electrode in a substrate glass furnace according to some embodiments of the present disclosure.

Embodiments of the present disclosure provide a device for measuring the high-temperature resistivity of the tin oxide electrode in the substrate glass furnace. The high-temperature resistivity refers to a resistivity at a high temperature. The substrate glass furnace refers to a furnace for preparing the substrate glass. The substrate glass may be manufactured by the furnace with a tin oxide electrode as a heating element. Using the device for measuring the high-temperature resistivity of the tin oxide electrode in the substrate glass furnace, high-temperature volume resistivities of the tin oxide electrode in the furnace at different temperatures may be measured, thus providing strong theoretical support and basis for the current and power settings for the tin oxide electrode when being powered, and meeting the requirements for the manufacturing of the substrate glass.

The tin oxide electrode refers to an electrode manufactured based on a tin oxide material, for example, an electrode made of tin dioxide (SnO₂). The tin oxide has good chemical stability and is suitable for application in a wide range of environmental conditions, for example, the fields of sensor technology (e.g., gas sensors), solar cells, transparent conductive electrodes, and lithium-ion batteries. The tin oxide electrode also has a good transparent conductivity, which makes it to be an ideal material for manufacturing transparent conductive electrodes, for example, for applications in displays and touch screens.

In some embodiments, as shown in FIG. 1, the device 100 for measuring the high-temperature resistivity of the tin oxide electrode in the substrate glass furnace (referred to as the measuring device hereinafter) includes a direct-current dual-arm bridge 110, a first platinum wire 120, a second platinum wire 130, a first platinum terminal 140, a second platinum terminal 150, a first insulating spacer 160, and a second insulating spacer 170. One end of the direct-current dual-arm bridge 110 is connected to one end of the first platinum wire 120, and the other end of the direct-current dual-arm bridge 110 is connected to one end of the second platinum wire 130. The other end of the first platinum wire 120 is connected to the first platinum terminal 140, and the first insulating spacer 160 is provided on the upper side of the first platinum terminal 140 (in the direction A as shown in FIG. 1). The other end of the second platinum wire 130 is connected to the second platinum terminal 150, and the second insulating spacer 170 is provided on a lower side of the second platinum terminal 150 (in the direction B as shown in FIG. 1).

The direct-current dual-arm bridge 110 is a circuit device used to accurately measure the resistance.

The platinum wire refers to a wire made from the metal platinum. Different platinum wires may be connected to each end of the direct-current dual-arm bridge.

The platinum wire has characteristics such as high melting point, corrosion resistance, good electrical conductivity, and chemical inertness. Therefore, the platinum wire may be applied in high-temperature and corrosion-resistance scenarios, such as glass manufacturing.

In some embodiments, as shown in FIG. 1, the first platinum wire 120 may be connected to an end of the direct-current dual-arm bridge 110 along the direction A, and the second platinum wire 130 may be connected to an end of the direct-current dual-arm bridge 110 along the direction B. Through the first platinum wire 120 and the second platinum wire 130, the ends of the direct-current dual-arm bridge 110 may be connected to a resistor to be measured (e.g., a columnar tin oxide electrode to be measured) and form a complete measurement loop.

The platinum terminal refers to an electrical connection assembly that uses platinum as a material or coating. The platinum terminal may utilize the excellent properties of platinum to provide reliable electrical conductivity and durability in scenarios requiring high-temperature resistance, corrosion resistance, and long-term stable performance.

The insulating spacer refers to a material that provides electrical insulation. The insulating spacer protects the functionality and safety of the device by preventing unintentional current transfer between conductive components. The insulating spacer has a plurality of shapes and sizes and may be made from a plurality of kinds of materials to meet different application requirements. In some embodiments, the insulating spacer may be made from an insulating material. In some embodiments, the insulating spacer may be made of a material such as rubber, plastic, mica, ceramic, or the like.

In some embodiments, as shown in FIG. 1, one end of the direct-current dual-arm bridge 110 along the direction A is connected to the upper surface of the columnar tin oxide electrode 180 to be measured (a side of the end surface of the columnar tin oxide electrode 180 to be measured that is close to the direction A) through the first platinum wire 120 and the first platinum terminal 140 in turn, and the upper surface of the columnar tin oxide electrode 180 to be measured is insulated from other components through the first insulating spacer 160 on the upper side of the first platinum terminal 140. One end of the direct-current dual-arm bridge 110 along the direction B is connected to the lower surface of the columnar tin oxide electrode 180 to be measured (a side of the end surface of the columnar tin oxide electrode 180 to be measured near the direction B) through the second platinum wire 130 and the second platinum terminal 150 in turn, and the lower surface of the columnar tin oxide electrode 180 to be measured is insulated from other components through the second insulating spacer 170 on the lower side of the second platinum terminal 150.

In this way, the two ends of the direct-current dual-arm bridge 110 may respectively be connected to the two ends of the columnar tin oxide electrode 180 to be measured via the platinum wires and the platinum terminals, to measure the resistance value of the columnar tin oxide electrode 180 to be measured while being insulated from other components through insulating spacers.

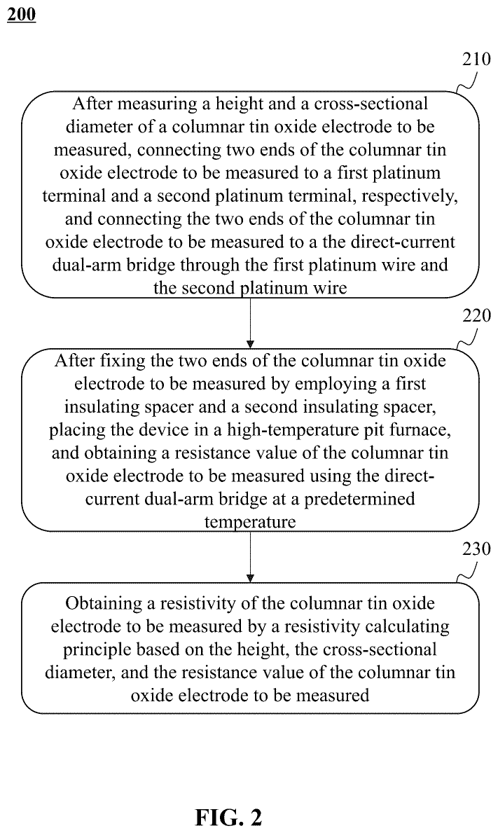

More descriptions regarding the columnar tin oxide electrode to be measured may be found in FIG. 2.

In some embodiments of the present disclosure, the direct-current dual-arm bridge is adopted to measure the resistance value of the tin oxide electrode, platinum terminals are connected at both ends of the tin oxide electrode through platinum wires, and the insulating spacers are provided on sides of the platinum terminals. The measurement principle of this device is simple and the structural cost of the device is very low, which realizes the use of the production line process data for repeated comparison verification and repeated reproduction testing, saving expensive equipment costs and outsourcing test costs, thereby reducing production costs.

In some embodiments, to ensure the accuracy of the resistivity measurement of the tin oxide electrode in the high-temperature pit furnace, the materials of both the first insulating spacer and the second insulating spacer are selected from an aluminum oxide material.

The aluminum oxide material has good electrical insulation, high-temperature resistance, chemical stability, etc. The insulating spacer made of aluminum oxide material combines the excellent properties of aluminum oxide with the application needs of spacers and is widely used in applications requiring high-temperature stability and electrical insulation.

In some embodiments, the aluminum oxide material has a resistivity of greater than 1×10³ Ω·cm above 1200° C., and the aluminum oxide material has an alumina oxide purity of no less than 99.99%, ensuring stability during measurement.

In some embodiments, the resistivity of the aluminum oxide material above 1200° C. is greater than 1×10³ Ω·cm, 1×10⁵ Ω·cm, 1×10⁷ Ω·cm, 1×10⁹ Ω·cm, 1×10¹¹ Ω·cm, or the like. In some embodiments, the resistivity of the aluminum oxide material above 1200° C. is within a range of 1×10³ Ω·cm-1×10¹⁴ Ω·cm, 1×10⁵ Ω·cm-1×10¹⁴ Ω·cm, 1×10⁷ Ω·cm-1×10¹⁴ Ω·cm, 1×10⁹ Ω·cm-1×10¹⁴ Ω·cm, 1×10¹⁰ Ω·cm-1×10¹⁴ Ω·cm, 1×10¹¹ Ω·cm-1×10¹³ Ω·cm, etc.

In some embodiments, the alumina oxide purity of the aluminum oxide material is not less than 99.99%, 99.991%, 99.992%, 99.995%, 99.999%, 99%, 99.1%, 99.2%, 99.3%, 99.4%, 99.5%, 99.6%, 99.7%, 99.8%, 99.9%, etc.

In the embodiments of the present disclosure, in the manufacturing scenario of the substrate glass, the insulating spacer is manufactured using aluminum oxide material with an aluminum oxide purity of more than 99.99%, which avoids the undesirable effects of impurities in the aluminum oxide material.

In some embodiments, the first platinum terminal 140 and the second platinum terminal 150 may be set up in a plurality of ways. For example, the first platinum terminal 140 and the second platinum terminal 150 may be provided on the upper surface and the lower surface of the columnar tin oxide electrode 180 to be measured. As another example, the first platinum terminal 140 and the second platinum terminal 150 may be provided on the side surface of the columnar tin oxide electrode 180 to be measured.

In some embodiments, as shown in FIG. 1, the first platinum terminal 140 and the second platinum terminal 150 may be provided symmetrically above and below. For example, with a middle line x of the direct-current dual-arm bridge 110 as an axis, the first platinum terminal 140 may be provided on the upper surface of the columnar tin oxide electrode 180 to be measured (a side of the end surface of the columnar tin oxide electrode 180 to be measured near the direction A), the second platinum terminal 150 may be provided on the lower surface of the columnar tin oxide electrode 180 to be measured (a side of the end face of the columnar tin oxide electrode 180 to be measured near the direction B), and the first platinum terminal 140 and the second platinum terminal 150 may be symmetrical relative to the axis x.

In the embodiment of the present disclosure, the symmetrical setting of the platinum terminals may ensure a balanced overall performance of the measurement loop formed by the measuring device during the measurement of the columnar tin oxide electrode to be measured, ensuring the consistency and stability of the signal transmission, improving the stability of the measurement loop and reliability, etc.

In some embodiments, a predetermined distance is maintained between the first platinum terminal and the second platinum terminal, and the predetermined distance is greater than the height of the columnar tin oxide electrode to be measured. The predetermined distance maintained between the first platinum terminal and the second platinum terminal may form an accommodating space to accommodate the columnar tin oxide electrode to be measured.

The predetermined distance may be manually set. The height of the columnar tin oxide electrode to be measured is a length between the upper surface and the lower surface of the tin oxide electrode, i.e., a length along an extension direction of the column. If the predetermined distance is less than the height of the columnar tin oxide electrode to be measured, the measuring device cannot measure the overall resistance of the columnar tin oxide electrode.

In the embodiment of the present disclosure, maintaining the predetermined distance between the first platinum terminal and the second platinum terminal may avoid mutual influence between the two, and the predetermined distance is greater than the height of the columnar tin oxide electrode to be measured, so as to avoid the situation where only a part of the resistance of the tin oxide electrode is measured.

FIG. 2 is a flowchart illustrating an exemplary method for measuring a high-temperature resistivity of a tin oxide electrode in a substrate glass furnace according to some embodiments of the present disclosure. In some embodiments, process 200 may be performed manually.

In order to ensure the reliability of the above-described measuring device, embodiments of the present disclosure provide a method for measuring the high-temperature resistivity of the tin oxide electrode in the substrate glass furnace, as illustrated in FIG. 2, and the process 200 includes the following operations.

In 210, after measuring the height and the cross-sectional diameter of the columnar tin oxide electrode to be measured, two ends of the columnar tin oxide electrode to be measured are connected to the first platinum terminal and the second platinum terminal, respectively, and the two ends of the columnar tin oxide electrode to be measured are connected to the direct-current dual-arm bridge through the first platinum wire and the second platinum wire.

More descriptions regarding the first platinum terminal, the second platinum terminal, the first platinum wire, the second platinum wire, and the direct-current dual-arm bridge may be found in FIG. 1 and related descriptions thereof.

The columnar tin oxide electrode to be measured refers to a columnar tin oxide electrode that needs to be measured. The columnar tin oxide electrode has a columnar or vertical array structure and is typically used to increase surface area and electrical activity. The shapes of the upper and lower surfaces of the columnar tin oxide electrode may include a circle, an oval, a quadrilateral, a hexagon, an octagon, or the like. In embodiments of the present disclosure, the material of the tin oxide electrode applied in the furnace of the production line is typically processed into a cylindrical shape.

As previously described, if the columnar tin oxide electrode to be measured is cylindrical, the height of the columnar tin oxide electrode to be measured is the length along the extension direction of the column. The cross-sectional diameter of the columnar tin oxide electrode to be measured is the diameter of the circle of the upper or lower surface.

In some embodiments, the height and cross-sectional diameter of the columnar tin oxide electrode to be measured may be manually measured and recorded by a ruler.

After connecting the two ends of the columnar tin oxide electrode to be measured to the first platinum terminal and the second platinum terminal respectively, the columnar tin oxide electrode to be measured is connected to the device for measuring the high-temperature resistivity of the tin oxide electrode in the substrate glass furnace. Two ends of the columnar tin oxide electrode to be measured are respectively connected to the first platinum wire and the second platinum wire and form a circuit with the direct-current dual-arm bridge. Thus, the measuring device may measure the resistance value between the two ends of the columnar tin oxide electrode to be measured.

In 220, after fixing the two ends of the columnar tin oxide electrode to be measured by employing the first insulating spacer and the second insulating spacer, the measuring device is placed in a high-temperature pit furnace, and the resistance value of the columnar tin oxide electrode to be measured is obtained using the direct-current dual-arm bridge at a predetermined temperature.

More descriptions regarding the first insulating spacer and the second insulating spacer may be found in FIG. 1 and related descriptions thereof.

In some embodiments, the insulating spacers may be fixed to the two ends of the columnar tin oxide electrode to be measured in a variety of manners. For example, the insulating spacer is affixed to the tin oxide electrode by means of a special glue or adhesive (e.g., a non-conductive adhesive including epoxy, polyurethane, acrylate, etc.). As another example, the tin oxide electrode and the insulating spacer may be fixed by a jig or bracket to ensure good contact between the two. As yet another example, it can be fixed by using high-temperature resistant and chemically stable sealants (e.g., silicone). The manner of fixing the insulating spacer to the columnar tin oxide electrode to be measured may be set according to actual needs and needs to ensure that it does not adversely affect the electrical conductivity, the chemical stability of the tin oxide electrode, and the overall performance of the measurement device.

In some embodiments, the measuring device may be placed in a high-temperature pit furnace to test the high-temperature volume resistivity of the tin oxide electrode at different temperatures.

The high-temperature pit furnace refers to a kind of industrial device designed for high-temperature heat treatment. The workspace of the high-temperature pit furnace is in the shape of a vertical pit, which is suitable for treating workpieces of long rod shape or special shapes and is capable of reaching a temperature of 1600° C. or higher. The high-temperature pit furnace is suitable for treating materials that require a high-temperature environment such as substrate glass manufacturing.

In some embodiments, a high-temperature pit furnace in a laboratory may be utilized for the heating program setting, to measure and obtain the resistance values of the tin oxide electrode at different temperatures, which can be further used to calculate the high-temperature volume resistivity of the tin oxide electrode at different temperatures. The high-temperature volume resistivity refers to the resistance encountered by a current passing through a unit volume of a material at a high temperature.

The predetermined temperature refers to a temperature measurement interval of the high-temperature pit furnace, i.e., a temperature interval in which resistivity needs to be measured.

In some embodiments, the predetermined temperature is within a range of 400° C.-1600° C.

In some embodiments, the predetermined temperature may be within one of the ranges of 400° C.-1500° C., 400° C.-1400° C., 500° C.-1500° C., 500° C.-1600° C., or the like. In some embodiments, the predetermined temperature may be 400° C., 500° C., 600° C., 700° C., 800° C., 900° C., 1000° C., 1200° C., 1300° C., 1400° C., 1500° C., or the like.

Different application scenarios require different temperatures, so the resistivities of the tin oxide electrode at a plurality of temperature intervals may be measured by setting appropriate predetermined temperatures, which provide strong theoretical support for the setting/application and accurate calculation of the electrical parameters of tin oxide electrode in the process temperature interval of the production line process.

The heating rate of the predetermined temperature refers to the amplitude of the temperature of the furnace rising per unit of time. The heating rate of the predetermined temperature may be adjusted according to specific processes and material requirements.

In some embodiments, to apply to the manufacturing process of the substrate glass, the heating rate is within a range of 4° C./min-6° C./min. The heating rate may be the same or similar to the heating rate of the manufacturing process of the substrate glass.

If the heating rate is too high, the measurement of the resistance value of the tin oxide electrode may be inaccurate. If the heating rate is too low, the heating time may be too long.

In some embodiments, the heating rate of the predetermined temperature may be within one of the ranges of 4° C./min-5.8° C./min, 4° C./min-5.5° C./min, 4° C./min-5.2° C./min, 4° C./min-5° C./min, 4.2° C./min-6° C./min, 4.5° C./min-6° C./min, 4.8° C./min-6° C./min, etc. In some embodiments, the heating rate of the predetermined temperature may be 4° C./min, 4.2° C./min, 4.5° C./min, 4.8° C./min, 5° C./min, 5.2° C./min, 5.5° C./min, 5.8° C./min, 6° C./min, etc.

In some embodiments, during the heating process of the high-temperature pit furnace (at the predetermined temperature), the resistance value of the columnar tin oxide electrode to be measured may be measured and recorded using the direct-current dual-arm bridge at intervals of 100° C. For example, the resistance value of the columnar tin oxide electrode to be measured may be measured and recorded once when the temperature is 400° C., 500° C., 600° C., . . . , and 1600° C. At this time, the resistance value of the columnar tin oxide electrode to be measured is the resistance value displayed by the direct-current dual-arm bridge, i.e., the resistance value displayed by the direct-current dual-arm bridge may be recorded as the resistance value of the columnar tin oxide electrode to be measured.

In the embodiments of the present disclosure, setting a temperature interval of 100° C. to measure the resistance values of the columnar tin oxide electrode to be measured not only obtains the change in resistance of the columnar tin oxide electrode to be measured but also avoids that a too small temperature interval to cause the resistance data of adjacent temperatures to change too little, resulting in meaningless measurements.

In 230, the resistivity of the columnar tin oxide electrode to be measured is obtained by a resistivity calculating principle based on the height, the cross-sectional diameter, and the resistance value of the columnar tin oxide electrode to be measured.

The resistivity calculating principle refers to a manner of calculating resistivity based on the geometrical properties and resistance values of a material. In some embodiments, the resistivity of the columnar tin oxide electrode to be measured may be calculated based on the height, the cross-sectional diameter, the cross-sectional area, and the measured resistance values of the columnar tin oxide electrode to be measured. The cross-sectional area refers to a circular area of the upper or lower surface of the columnar tin oxide electrode to be measured. The cross-sectional area may be obtained based on the cross-sectional diameter. For example, the cross-sectional area is x times the square of the cross-sectional radius. The cross-sectional radius is half the cross-sectional diameter.

In some embodiments, the resistivity calculating principle includes the following equations (1) and (2):

$${ρ}_{T} = \frac{R S}{L} , \qquad ( 1 )$$

$$S = π \times \frac{{D}^{2}}{4} , \qquad ( 2 )$$

where L denotes the height of the columnar tin oxide electrode to be measured, D denotes the cross-sectional diameter of the columnar tin oxide electrode to be measured, S denotes the cross-sectional area of the columnar tin oxide electrode to be measured, R denotes the resistance value of the columnar tin oxide electrode to be measured, and ρ_{T} denotes the resistivity of the columnar tin oxide electrode to be measured. The volume resistivities of the columnar tin oxide electrode at different temperatures may be calculated by measuring the resistance values R of the columnar tin oxide electrode to be measured at different temperatures.

In some embodiments, sample 1 and sample 2 of the columnar tin oxide electrode are tested to obtain the resistance values of sample 1 and sample 2 at different temperatures, the above equations (1) and (2) are substituted, and specific test results may be obtained as shown in Table 1 below.

TABLE 1
Volume resistivities ρ_{T} of sample
1 and sample 2 at different temperatures

| | | |
|---|---|---|
| Temperature ° C. | Sample 1 | Sample 2 |

| | | | | |
|---|---|---|---|---|
| 400 | 29 | Ω · cm | 36 | Ω · cm |
| 500 | 9.6 | Ω · cm | 8.3 | Ω · cm |
| 600 | 6.8 | Ω · cm | 7.2 | Ω · cm |
| 700 | 1.5 | Ω · cm | 1.9 | Ω · cm |
| 800 | 0.5 | Ω · cm | 0.7 | Ω · cm |
| 900 | 0.1 | Ω · cm | 0.13 | Ω · cm |
| 1000 | 0.06 | Ω · cm | 0.09 | Ω · cm |
| 1100 | 0.008 | Ω · cm | 0.007 | Ω · cm |
| 1200 | 0.003 | Ω · cm | 0.005 | Ω · cm |
| 1300 | 0.002 | Ω · cm | 0.003 | Ω · cm |
| 1400 | 0.0018 | Ω · cm | 0.002 | Ω · cm |
| 1500 | 0.0015 | Ω · cm | 0.0018 | Ω · cm |
| 1600 | 0.0015 | Ω · cm | 0.0016 | Ω · cm |

Note:
Sample 1 and Sample 2 have a diameter of 150 mm and a height of 240 mm.

As can be seen in Table 1, the resistivities of sample 1 and sample 2 decrease as the temperature continues to rise. The lower the temperature, the greater the decrease magnitude of the resistivity; the higher the temperature, the smaller the decrease magnitude of the resistivity.

In the embodiments of the present disclosure, based on the resistivity calculating principle, by processing the material of the tin oxide electrode applied in the furnace in the production line into a cylindrical shape, and further using the above measuring device, the volume resistivities of the tin oxide electrode at different temperatures may be calculated through the measurement of the resistance values R at different temperatures, of which the principle of temperature measurement is simple, the structural cost of the device is very low, and it is simple, reliable, and easy to operate, thus realizing the use of the production line process data for repeated comparison verification and repeated reproduction testing, and saving expensive equipment costs and outsourcing test costs, thereby providing strong theoretical support for the setting/application and accurate calculation of the electrical parameters of tin oxide electrode in the process temperature interval of the production line process.

It should be noted that the foregoing description of process 200 is for the purpose of exemplification and illustration only, and does not limit the scope of application of the present disclosure. For a person skilled in the art, various corrections and changes can be made to the process 200 under the guidance of the present disclosure. However, these corrections and changes remain within the scope of the present disclosure.

Having thus described the basic concepts, it may be rather apparent to those skilled in the art after reading this detailed disclosure that the foregoing detailed disclosure is intended to be presented by way of example only and is not limiting. Although not explicitly stated here, those skilled in the art may make various modifications, improvements, and amendments to the present disclosure. These alterations, improvements, and amendments are intended to be suggested by this disclosure and are within the spirit and scope of the exemplary embodiments of the present disclosure.

Moreover, certain terminology has been used to describe embodiments of the present disclosure. For example, the terms “one embodiment,” “an embodiment,” and/or “some embodiments” mean that a particular feature, structure, or feature described in connection with the embodiment is included in at least one embodiment of the present disclosure. Therefore, it is emphasized and should be appreciated that two or more references to “an embodiment,” “one embodiment,” or “an alternative embodiment” in various portions of the present disclosure are not necessarily all referring to the same embodiment. In addition, some features, structures, or characteristics of one or more embodiments in the present disclosure may be properly combined.

Furthermore, the recited order of processing elements or sequences, or the use of numbers, letters, or other designations, therefore, is not intended to limit the claimed processes and methods to any order except as may be specified in the claims. Although the above disclosure discusses some embodiments of the invention currently considered useful by various examples, it should be understood that such details are for illustrative purposes only, and the additional claims are not limited to the disclosed embodiments. Instead, the claims are intended to cover all combinations of corrections and equivalents consistent with the substance and scope of the embodiments of the present disclosure. For example, although the implementation of various components described above may be embodied in a hardware device, it may also be implemented as a software only solution, e.g., an installation on an existing server or mobile device.

Similarly, it should be appreciated that in the foregoing description of embodiments of the present disclosure, various features are sometimes grouped together in a single embodiment, figure, or description thereof for the purpose of streamlining the disclosure aiding in the understanding of one or more of the various embodiments. However, this disclosure does not mean that object of the present disclosure requires more features than the features mentioned in the claims. Rather, claimed subject matter may lie in less than all features of a single foregoing disclosed embodiment.

In some embodiments, the numbers expressing quantities or properties used to describe and claim certain embodiments of the present disclosure are to be understood as being modified in some instances by the term “about,” “approximate,” or “substantially.” For example, “about,” “approximate,” or “substantially” may indicate ±20% variation of the value it describes, unless otherwise stated. Accordingly, in some embodiments, the numerical parameters set forth in the written description and attached claims are approximations that may vary depending upon the desired properties sought to be obtained by a particular embodiment. In some embodiments, the numerical parameters should be construed in light of the number of reported significant digits and by applying ordinary rounding techniques. Notwithstanding that the numerical ranges and parameters setting forth the broad scope of some embodiments of the present disclosure are approximations, the numerical values set forth in the specific examples are reported as precisely as practicable.

Each of the patents, patent applications, publications of patent applications, and other material, such as articles, books, specifications, publications, documents, things, and/or the like, referenced herein is hereby incorporated herein by this reference in its entirety for all purposes. History application documents that are inconsistent or conflictive with the contents of the present disclosure are excluded, as well as documents (currently or subsequently appended to the present specification) limiting the broadest scope of the claims of the present disclosure. By way of example, should there be any inconsistency or conflict between the description, definition, and/or the use of a term associated with any of the incorporated material and that associated with the present document, the description, definition, and/or the use of the term in the present document shall prevail.

In closing, it is to be understood that the embodiments of the present disclosure disclosed herein are illustrative of the principles of the embodiments of the present disclosure. Other modifications that may be employed may be within the scope of the present disclosure. Thus, by way of example, but not of limitation, alternative configurations of the embodiments of the present disclosure may be utilized in accordance with the teachings herein. Accordingly, embodiments of the present disclosure are not limited to that precisely as shown and described.

What is claimed is:

1. A device for measuring a high-temperature resistivity of a tin oxide electrode in a substrate glass furnace, comprising:
a direct-current dual-arm bridge, wherein one end of the direct-current dual-arm bridge is connected to one end of a first platinum wire, and the other end of the direct-current dual-arm bridge is connected to one end of a second platinum wire;
the other end of the first platinum wire is connected to a first platinum terminal, and a first insulating spacer is provided on an upper side of the first platinum terminal; and
the other end of the second platinum wire is connected to a second platinum terminal, and a second insulating spacer is provided on a lower side of the second platinum terminal.

2. The device of claim 1, wherein the first insulating spacer and the second insulating spacer are made of an aluminum oxide material.

3. The device of claim 2, wherein the alumina oxide material has a resistivity of greater than 1×10³ Ω·cm above 1200° C., and an alumina oxide purity of the alumina oxide material is no less than 99.99%.

4. The device of claim 1, wherein the first platinum terminal and the second platinum terminal are symmetrically provided.

5. The device of claim 1, wherein a predetermined distance is maintained between the first platinum terminal and the second platinum terminal, the predetermined distance being greater than a height of a columnar tin oxide electrode to be measured.

6. A method for measuring a high-temperature resistivity of a tin oxide electrode in a substrate glass furnace, the method being implemented based on a device for measuring a high-temperature resistivity of a tin oxide electrode in a substrate glass furnace, comprising:
a direct-current dual-arm bridge, wherein one end of the direct-current dual-arm bridge is connected to one end of a first platinum wire, and the other end of the direct-current dual-arm bridge is connected to one end of a second platinum wire;
the other end of the first platinum wire is connected to a first platinum terminal, and a first insulating spacer is provided on an upper side of the first platinum terminal; and
the other end of the second platinum wire is connected to a second platinum terminal, and a second insulating spacer is provided on a lower side of the second platinum terminal,
wherein the method comprises:
after measuring a height and a cross-sectional diameter of a columnar tin oxide electrode to be measured, connecting two ends of the columnar tin oxide electrode to be measured to the first platinum terminal and the second platinum terminal, respectively, and connecting the two ends of the columnar tin oxide electrode to be measured to the direct-current dual-arm bridge through the first platinum wire and the second platinum wire;
after fixing the two ends of the columnar tin oxide electrode to be measured by employing a first insulating spacer and a second insulating spacer, placing the device in a high-temperature pit furnace;
obtaining a resistance value of the columnar tin oxide electrode to be measured using the direct-current dual-arm bridge at a predetermined temperature; and
obtaining a resistivity of the columnar tin oxide electrode to be measured by a resistivity calculating principle based on the height, the cross-sectional diameter, and the resistance value of the columnar tin oxide electrode to be measured.

7. The method of claim 6, wherein the predetermined temperature is within a range of 400° C.-1600° C.

8. The method of claim 6, wherein a heating rate of the predetermined temperature is within a range of 4° C./min-6° C./min.

9. The method of claim 6, wherein the obtaining a resistance value of the columnar tin oxide electrode to be measured using the direct-current dual-arm bridge at a predetermined temperature comprises:
measuring and recording, at intervals of 100° C., the resistance value of the columnar tin oxide electrode to be measured using the direct-current dual-arm bridge at the predetermined temperature.

10. The method of claim 6, wherein the resistivity calculating principle includes:
$${ρ}_{T} = \frac{R S}{L}$$
$$S = π \times \frac{{D}^{2}}{4}$$
wherein ρ_{T} denotes the resistivity of the columnar tin oxide electrode to be measured, R denotes the resistance value of the columnar tin oxide electrode to be measured, S denotes a cross-sectional area of the columnar tin oxide electrode to be measured, D denotes the cross-sectional diameter of the columnar tin oxide electrode to be measured, and L denotes the height of the columnar tin oxide electrode to be measured.
